(19) United States
(12) Patent Application Publication
(10) Pub. No.: US 2010/0258188 A1
(43) Pub. Date: Oct. 14, 2010

(54) Thin Film Type Solar Cell and Method for Manufacturing the Same

(76) Inventor: Ki Se Lee, Gyeonggi-do (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/809,583

(22) PCT Filed: Dec. 19, 2008
(86) PCT No.: PCT/KR2008/007561

§ 371 Date: Jun. 19, 2010

(30) Foreign Application Priority Data
Dec. 21, 2007 (KR) 10-2007-0134978

(51) Int. Cl. H01L 31/00; H01L 31/18

(52) U.S. Cl. 136/261; 438/69; 257/E31.032; 257/E31.127

(57) ABSTRACT

A thin film type solar cell and a method for manufacturing the same is disclosed, which the thin film type solar cell comprises a front electrode, a semiconductor layer, and a rear electrode sequentially deposited on a substrate; and a buffer layer between the substrate and the front electrode so as to enhance an adhesive strength between the substrate and the front electrode, and to improve transmittance of solar ray incident through the substrate.

### TECHNICAL FIELD

The present invention relates to a solar cell, and more particularly, to a thin film type solar cell.

### BACKGROUND ART

A solar cell with a property of semiconductor converts a light energy into an electric energy.

A structure and principle of the solar cell according to the related art will be briefly explained as follows. The solar cell is formed in a PN-junction structure where a positive(P)-type semiconductor makes a junction with a negative(N)-type semiconductor. When a solar ray is incident on the solar cell with the PN-junction structure, holes(+) and electrons(−) are generated in the semiconductor owing to the energy of the solar ray. By an electric field generated in an PN-junction area, the holes(+) are drifted toward the P-type semiconductor, and the electrons(−) are drifted toward the N-type semiconductor, whereby an electric power is produced with an occurrence of electric potential.

The solar cell can be largely classified into a wafer type solar cell and a thin film type solar cell.

The wafer type solar cell uses a wafer made of a semiconductor material such as silicon. In the meantime, the thin film type solar cell is manufactured by forming a semiconductor in type of a thin film on a glass substrate.

With respect to efficiency, the wafer type solar cell is better than the thin film type solar cell. However, in the case of the wafer type solar cell, it is difficult to realize a small thickness due to difficulty in performance of the manufacturing process. In addition, the wafer type solar cell uses a high-priced semiconductor substrate, whereby its manufacturing cost is increased.

Even though the thin film type solar cell is inferior in efficiency to the wafer type solar cell, the thin film type solar cell has advantages such as realization of thin profile and use of low-priced material. Accordingly, the thin film type solar cell is suitable for a mass production.

The thin film type solar cell is manufactured by sequential steps of forming a front electrode on a glass substrate, forming a semiconductor layer on the front electrode, and forming a rear electrode on the semiconductor layer.

Hereinafter, a related art thin film type solar cell will be explained with reference to FIG. 1.

FIG. 1 is a cross section view illustrating a related art thin film type solar cell.

As shown in FIG. 1, the related art thin film type solar cell includes a substrate 10, a front electrode 30 on the substrate 10, a semiconductor layer 40 on the front electrode 30, and a rear electrode 60 on the semiconductor layer 40.

The front electrode 30 forms a positive(+) electrode of the thin film type solar cell. Also, the front electrode 30 is made of a transparent conductive material since the front electrode 30 corresponds to a solar ray incidence face.

The semiconductor layer 40 is made of a semiconductor material, for example, silicon. The semiconductor layer 40 is formed in a PIN structure with a P(positive)-type silicon layer, an I(intrinsic)-type silicon layer, and an N(negative)-type silicon layer deposited in sequence.

The rear electrode 60 forms a negative(−) electrode of the thin film type solar cell. The rear electrode 60 is made of a conductive metal material, for example, aluminum.

The related art thin film type solar cell has the following disadvantages.

Generally, the related art thin film type solar cell uses the substrate 10 made of glass. However, if manufacturing the thin film type solar cell with the glass substrate 10, a direction of solar ray incident on the substrate 10 is not very different from a direction of solar ray entering the front electrode 30 through the substrate 10. Thus, it is difficult to improve the efficiency of solar cell due to the limit in collection of the solar ray.

Also, the front electrode 30 made of the transparent conductive material has a low adhesive strength to the substrate 100.

### DISCLOSURE

### Technical Problem

Therefore, the present invention has been made in view of the above problems, and it is an object of the present invention to provide a thin film type solar cell and a method for manufacturing the same, which is capable of improving the efficiency of solar cell by enhancing an adhesive strength between a front electrode and a substrate, and improving transmittance of solar ray through the high efficiency in collection of the solar ray.

### Technical Solution

To achieve these objects and other advantages and in accordance with the purpose of the invention, as embodied and broadly described herein, a thin film type solar cell provided with a front electrode, a semiconductor layer, and a rear electrode sequentially deposited on a substrate, comprises a buffer layer between the substrate and the front electrode so as to enhance an adhesive strength between the substrate and the front electrode, and to improve transmittance of solar ray incident through the substrate.

At this time, the buffer layer is formed of a transparent material whose refractive index is higher than that of the substrate.

Also, the buffer layer is formed of a transparent material whose refractive index is within a range between 1.9 and 2.3.

The buffer layer is formed at a thickness between 10001 and 3000 Å.

The buffer layer is formed of a material selected from a group comprised of TiO₂, SiN, or SiO₂.

The buffer layer is comprised of a plurality of sub-layers.

In addition, the thin film type solar cell further includes a transparent conductive layer between the semiconductor layer and the rear electrode.

In another aspect of the present invention, a method for manufacturing a thin film type solar cell comprises forming a buffer layer on a substrate; forming a front electrode on the buffer layer; forming a semiconductor layer on the front electrode; and forming a rear electrode on the semiconductor layer.

At this time, the buffer layer is formed of a transparent material whose refractive index is higher than that of the substrate.

Also, the buffer layer is formed of a transparent material whose refractive index is within a range between 1.9 and 2.3.

The buffer layer is formed at a thickness between 10001 and 3000 Å.

The buffer layer is formed of a material selected from a group comprised of TiO₂, SiN, or SiO₂.

The buffer layer is comprised of a plurality of sub-layers.

In addition, the method further includes forming a transparent conductive layer between the semiconductor layer and the rear electrode.

### ADVANTAGEOUS EFFECTS

The thin film type solar cell according to the present invention and the method for manufacturing the same has the following advantages.

According as the buffer layer is formed between the substrate and the front electrode, it is possible to enhance the adhesive strength between the substrate and the front electrode, and to improve the transmittance of solar ray incident through the substrate, thereby resulting in the high efficiency of solar cell.

Owing to the buffer layer made of the transparent material with the refractive index of 1.9 to 2.3, the transmittance of solar ray can be maximized through the minimized reflection of solar ray.

Also, the buffer layer is formed at a thickness between 10001 and 3000 Å, so that it is possible to maximize the transmittance of solar ray with the minimized reflection of solar ray.

### DESCRIPTION OF DRAWINGS

FIG. 1 is a cross section view illustrating a related art thin film type solar cell.

FIG. 2 is a cross section view illustrating a thin film type solar cell according to one embodiment of the present invention.

FIGS. 3A to 3E are cross section views illustrating a method for manufacturing a thin film type solar cell according to one embodiment of the present invention.

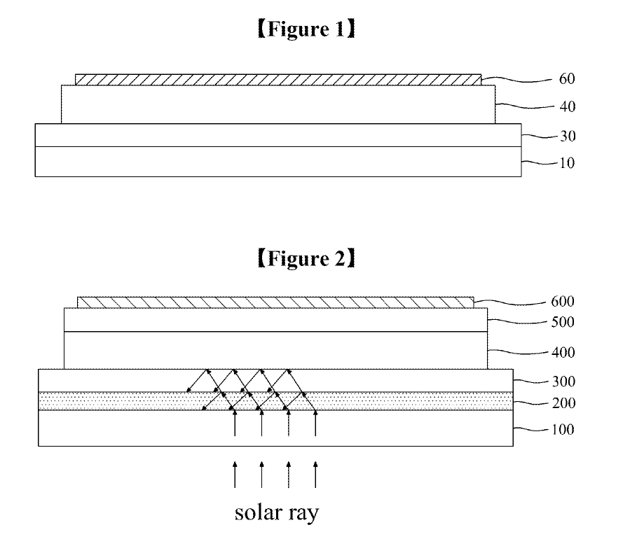

### BEST MODE

Reference will now be made in detail to the preferred embodiments of the present invention, examples of which are illustrated in the accompanying drawings. Wherever possible, the same reference numbers will be used throughout the drawings to refer to the same or like parts.

Hereinafter, a thin film type solar cell according to the present invention and a method for manufacturing the same will be explained with reference to the accompanying drawings.

<Thin Film Type Solar Cell>

FIG. 2 is a cross section view illustrating a thin film type solar cell according to one embodiment of the present invention.

As shown in FIG. 2, the thin film type solar cell according to one embodiment of the present invention includes a substrate 100, a buffer layer 200, a front electrode 300, a semiconductor layer 400, a transparent conductive layer 500, and a rear electrode 600.

At this time, the substrate 100 is formed of glass or transparent plastic.

The buffer layer 200 formed between the substrate 100 and the front electrode 300 enhances an adhesive strength therebetween. Also, the buffer layer 200 improves transmittance of solar ray incident through the substrate 100.

Preferably, the buffer layer 200 is formed of a transparent material whose refractive index is higher than that of the substrate 100. When forming the buffer layer 200 with the high refractive index, a path of solar ray passing through the buffer layer 200 is changed variously thereby increasing the total amount of solar ray transmitted to the inside of the thin film type solar cell. Especially, it is preferable that the buffer layer 200 be formed of the transparent material with the refractive index in a range between 1.9 and 2.3, since the reflection of the solar ray can be minimized within the range.

In order to maximize the transmittance of solar ray, it is important to change the path of solar ray variously, and to prevent the incident solar ray from being lost by reflection. The aforementioned range of refractive index enables the minimized reflection of solar ray.

Preferably, the buffer layer 200 is formed of the transparent material with the refractive index of 1.9 to 2.3, which is capable of improving the transmittance of solar ray and enhancing the adhesive strength between the substrate 100 and the front electrode 300, for example, TiO₂, SiN, or SiO₂.

The buffer layer 200 is formed at a thickness between 10001 and 3000 Å. In order to minimize reflection of the solar ray, the buffer layer 200 is formed at a thickness of at least 10001. If the thickness of buffer layer 200 is above 3000 Å, the transmittance of solar ray may be deteriorated.

The buffer layer 200 may be comprised of a plurality of sub-layers with the different refractive indexes.

The front electrode 300 may be formed of a transparent conductive material, for example, ZnO, ZnO:B, ZnO:Al, ZnO:H, SnO₂, SnO₂:F, or ITO (Indium Tin Oxide).

Among the aforementioned transparent conductive materials for the front electrode 300, even though ZnO:B has the great membrane-property, ZnO:B is not suitable for a mass production of solar cell due to the low adhesive strength to glass.

However, since the thin film type solar cell according to the present invention additionally includes the buffer layer 200 for enhancing the adhesive strength between the substrate 100 and the front electrode 300, ZnO:B with the great membrane-property can be used for the front electrode 300, thereby resulting in high efficiency of the solar cell.

If the front electrode 300 is formed of ZnO:B, the buffer layer 200 is formed of TiO₂ so as to improve the adhesive strength between the substrate 100 and the front electrode 300, preferably.

A texturing process may be additionally performed to the front electrode 300. Through the texturing process, a surface of material layer is provided with an uneven surface, that is, a texture structure, by an etching process using photolithography, an anisotropic etching process using a chemical solution, or a mechanical scribing process. According as the texturing process is performed to the front electrode 300, a solar-ray reflection ratio on the solar cell is decreased and a solar-ray absorbing ratio on the solar cell is increased owing to a dispersion of the solar ray, thereby improving the solar cell efficiency.

The semiconductor layer 400 may be formed of a silicon-based semiconductor material. The semiconductor layer 400 may be formed in a PIN structure by sequentially depositing a P-type semiconductor layer, an I-type semiconductor layer, and an N-type semiconductor layer. In the semiconductor layer 400 with the PIN structure, depletion is generated in the I-type semiconductor layer by the P-type semiconductor layer and the N-type semiconductor layer, whereby an electric field occurs. Thus, electrons and holes generated by the solar ray are drifted by the electric field, and the drifted electrons and holes are collected in the N-type semiconductor layer and the P-type semiconductor layer, respectively.

If forming the semiconductor layer 400 with the PIN structure, the P-type semiconductor layer is positioned on the front electrode 300, and the I-type and N-type semiconductor layers are formed on the P-type semiconductor layer, preferably. This is because a drift mobility of the hole is less than a drift mobility of the electron. In order to maximize the collection efficiency by the incident ray, the P-type semiconductor layer is positioned adjacent to the solar ray incidence face.

The transparent conductive layer 500 may be formed of a transparent conductive material, for example, ZnO, ZnO:B, ZnO:Al, or Ag. It is possible to omit the transparent conductive layer 500. However, it is preferable that the transparent conductive layer 500 be provided so as to improve the efficiency of solar cell. That is, when forming the transparent conductive layer 500, the solar ray passes through the semiconductor layer 400, and then passes through the transparent conductive layer 500. In this case, the solar ray passing through the transparent conductive layer 500 is dispersed at different angles. Thus, after the solar ray is reflected on the rear electrode 600, the solar ray re-incidence ratio is increased on the semiconductor layer 400.

The rear electrode 600 may be formed of a metal material, for example, Ag, Al, Ag⁺Mo, Ag⁺Ni, or Ag⁺Cu.

<Method for Manufacturing Thin Film Type Solar Cell>

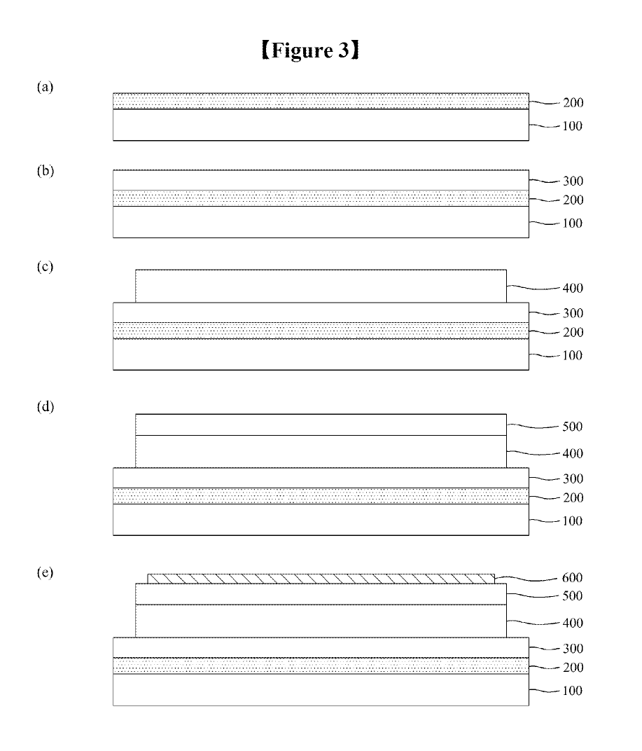

FIGS. 3A to 3E are cross section views illustrating a method for manufacturing a thin film type solar cell according to one embodiment of the present invention, wherein the detailed explanation for the same parts as those of the aforementioned embodiment will be omitted.

First, as shown in FIG. 3A, a buffer layer 200 is formed on a substrate 10. Preferably, the buffer layer 200 is formed of a transparent material whose refractive index is higher than that of the substrate 100. Particularly, the buffer layer 200 is formed of a transparent material with a refractive index of 1.9 to 2.3, which is capable of improving the transmittance of solar ray with the minimized reflection of solar ray.

The buffer layer 200 may be formed of TiO₂, SiN, or SiO₂.

The buffer layer 200 is formed at a thickness between 1000 Å and 3000 Å, preferably. The buffer layer 200 may be comprised of a plurality of sub-layers with the different refractive indexes.

Next, as shown in FIG. 3B, a front electrode 300 is formed on the buffer layer 200.

The front electrode 300 may be formed of a transparent conductive material, for example, ZnO, ZnO:B, ZnO:Al, ZnO:H, SnO₂, SnO₂:F, or ITO (Indium Tin Oxide) by sputtering or MOCVD (Metal Organic Chemical Vapor Deposition).

In order to maximize absorption of the solar ray, the front electrode 300 may be provided with an uneven surface by texturing.

As shown in FIG. 3C, a semiconductor layer 400 is formed on the front electrode 300.

The semiconductor layer 400 may be formed of a silicon-based semiconductor material. The semiconductor layer 400 may be formed in a PIN structure provided with a P-type semiconductor layer, an I-type semiconductor layer, and an N-type semiconductor layer deposited in sequence by a plasma CVD method.

As shown in FIG. 3D, a transparent conductive layer 500 is formed on the semiconductor layer 400.

The transparent conductive layer 500 may be formed of a transparent conductive material, for example, ZnO, ZnO:B, ZnO:Al, ZnO:H, or Ag by sputtering or MOCVD. The transparent conductive layer 500 may be omitted.

As shown in FIG. 3E, a rear electrode 600 is formed on the transparent conductive layer 500.

The rear electrode 600 may be formed of a metal material, for example, Ag, Al, Ag⁺Al, Ag⁺Mg, Ag⁺Mn, Ag⁺Zn, Ag⁺Mo, Ag⁺Ni, Ag⁺Cu, or Ag₊Al⁺Zn by a screen printing method, an inkjet printing method, a gravure printing method, or a micro-contact printing method.

In the case of the screen printing method, a material is transferred to a predetermined body through the use of squeeze. The inkjet printing method sprays a material onto a predetermined body through the use of inkjet, to thereby form a predetermined pattern thereon. In the case of the gravure printing method, a material is coated on an intaglio plate, and then the coated material is transferred to a predetermined body, thereby forming a predetermined pattern on the predetermined body. The micro-contact printing method forms a predetermined pattern of material on a predetermined body through the use of predetermined mold.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A thin film type solar cell, comprising:
a substrate;
a front electrode over the substrate;
a buffer layer between the substrate and the front electrode, wherein the buffer layer enhances an adhesive strength between the substrate and the front electrode and improves transmittance of solar rays incident on the substrate;
a semiconductor layer on or over the front electrode; and
a rear electrode on or over the semiconductor layer.

2. The thin film type solar cell according to claim 1, wherein the buffer layer comprises a transparent material having a higher refractive index than that of the substrate.

3. The thin film type solar cell according to claim 1, wherein the buffer layer comprises a transparent material having a refractive index within a range of from 1.9 to 2.3.

4. The thin film type solar cell according to claim 1, wherein the buffer layer has a thickness of from 1000 Å to 3000 Å.

5. The thin film type solar cell according to claim 1, wherein the buffer layer comprises TiO₂, SiN, or SiO₂.

6. The thin film type solar cell according to claim 1, wherein the buffer layer comprises a plurality of sub-layers.

7. The thin film type solar cell according to claim 1, further comprising a transparent conductive layer between the semiconductor layer and the rear electrode.

8. A method for manufacturing a thin film type solar cell comprising:
forming a buffer layer on or over a substrate;
forming a front electrode on or over the buffer layer;
forming a semiconductor layer on or over the front electrode; and
forming a rear electrode on or over the semiconductor layer.

9. The method according to claim 8, wherein the buffer layer comprises a transparent material having a higher refractive index than that of the substrate.

10. The method according to claim 8, wherein the refractive index of the transparent material is within a range of from 1.9 to 2.3.

11. The method according to claim 8, wherein the buffer layer has a thickness of from 1000 Å to 3000 Å.

12. The method according to claim 8, wherein the buffer layer comprises TiO₂, SiN, or SiO₂.

13. The method according to claim 8, wherein the buffer layer comprises a plurality of sub-layers.

14. The method according to claim 8, further comprising forming a transparent conductive layer on or over the semiconductor layer prior to forming the rear electrode.

15. The thin film type solar cell according to claim 6, wherein each of the plurality of sub-layers has a same refractive index.

16. The thin film type solar cell according to claim 6, wherein two or more of the plurality of sub-layers have different refractive indices.

17. The thin film type solar cell according to claim 6, wherein each of the plurality of sub-layers individually comprises TiO₂, SiN, or SiO₂.

18. The method according to claim 13, wherein each of the plurality of sub-layers has a same refractive index.

19. The method according to claim 13, wherein two or more of the plurality of sub-layers have different refractive indices.

20. The method according to claim 13, wherein each of the plurality of sub-layers individually comprises TiO₂, SiN, or SiO₂.
